(19) United States
(12) Patent Application Publication
(10) Pub. No.: US 2013/0052838 A1
(43) Pub. Date: Feb. 28, 2013

(54) ANNEALING METHOD TO REDUCE DEFECTS OF EPITAXIAL FILMS AND EPITAXIAL FILMS FORMED THEREWITH

(71) Applicants: I-Chiao Lin, Taipei City (TW); Chien-Min Sung, New Taipei City (TW)

(72) Inventors: I-Chiao Lin, Taipei City (TW); Chien-Min Sung, New Taipei City (TW)

(21) Appl. No.: 13/336,757

(22) Filed: Dec. 23, 2011

(30) Foreign Application Priority Data
Aug. 30, 2011 (TW) 100131006

(51) Int. Cl. H01L 21/26

(52) U.S. Cl. 438/796; 438/795; 257/E21.328

(57) ABSTRACT

An annealing method to reduce defects of epitaxial films and epitaxial films formed therewith. The annealing method includes features as follows: apply a pressure ranged from 10 MPa to 6,000 MPa to an epitaxial film grown on a substrate through a vapor phase deposition process and heat the epitaxial film at a temperature lower than the melting temperature of the epitaxial film. Through applying pressure to the epitaxial film, the lattice strain of the epitaxial film is alleviated, and therefore the defect density of the epitaxial film also decreases.

### FIELD OF THE INVENTION

The present invention relates to an annealing method for epitaxial films and epitaxial films formed therewith and particularly to an annealing method to effectively reduce defects of epitaxial films and epitaxial films formed therewith.

### BACKGROUND OF THE INVENTION

Epitaxy technique generally refers to a manufacturing process by which a single crystal film grows on a substrate, and the resulting single crystal film is also called as an epitaxial film. Generally, the substrate used for growing epitaxy is a single crystal material merely composed of single kind grain arranged in a specific direction. According to the differences between the epitaxial films and substrate in chemical compositions and lattice types, the epitaxial films can be classified into Homoepitaxy or Heteroepitaxy. The former means that the epitaxial film and substrate are formed of the same material, such as silicon or diamond. The later means that the epitaxial film and substrate formed of different materials, such as gallium nitride (GaN in short hereinafter) growing on the sapphire substrate, or aluminium gallium indium phosphide (AlGaInP) growing on the gallium arsenide (GaAs) substrate. The epitaxy technique can be employed to fabricate transistors of integrated circuits, detection elements in Micro-Electro-Mechanical Systems, electromagnetic wave transceiving films for telecommunication elements, vibration films for filtering signal, light emission layer for LEDs, or chips for testing Deoxyribonucleic acid (DNA), antibody or amino acid.

The epitaxy manufacturing process generally adopts Vapor phase epitaxy (VPE), Molecular beam epitaxy (MBE) or Liquid phase epitaxy (LPE). Take VPE for instance, at present Metal-organic chemical vapor deposition (MOCVD) or Hydride vapor phase epitaxy (HVPE) is commonly adopted in the industry. Reference techniques can be found in Japan Pat. Pub. No. JP 2010135598, U.S. Pat. Pub. Nos. 2006/0115933, 2010/0221902, 2007/0224786, 2010/0006024, 2011/0012109, and U.S. Pat. Nos. 7,943,492, 7,883,996 and 7,427,555, etc.

The principle of growing epitaxial film is that atoms utilizing the lattice of the substrate as a template to grow thereon and form a single crystal film. However, the epitaxial film obtained via the epitaxy manufacturing process is not exempt from producing material defects, such as voids, dislocations, faults or inclusions. On growing homoepitaxy the defects could be originated from indigenous defects of the substrate, uneven chemical composition on part of the substrate, impurities contained in the reaction chamber or gas source, or too fast deposition speed. On growing heteroepitaxy, aside from the aforesaid factors, differences in atom size and lattice direction between the epitaxial film and substrate also could increase the defect density of the epitaxial film. Furthermore, due to the atoms deposited on unstable locations of the substrate surface having greater energy, if the temperature during deposition is not high enough to make atom movement easier, the defects is more likely to be induced.

Take VPE for instance, as it is an unbalance growth, after deposition not only the atoms are hard to move on the substrate surface, but also the dislocated atoms cannot be vaporized to be re-deposited. As a result, defect density increases significantly. On the other hand, if the epitaxy manufacturing process is proximate to a balance growth, the atoms on the interface of liquid and solid phases can be deposited and melted at the same time, then defect density of the epitaxial film can be reduced. Take the epitaxial film of blue light LED as an example, VPE is usually carried out to grow GaN on the sapphire substrate. The stationary phase of GaN is a hexagonal (Wurtzite) crystal structure, sapphire is the (0002) plane of the hexagonal crystal structure. Hence lattice mismatch between the GaN and sapphire is greater than 13%. The sapphire substrate obtained by condensation and crystallization from liquid phase has dislocation density greater than 10⁹/cm², compared with the crystal ingot drawn from molten silicon having the dislocation density 10⁴/cm².

When the dislocation density of the epitaxial film is higher, the characteristics of its chip also deteriorate greater. Take an integrated circuit for instance, the dislocation density increasing would result in current signals decreasing and noise enhancing. On LED, the formation of the dislocation would reduce the number of photons generated by the Internal quantum effect. When temperature rises, dislocation size also increases and causes attenuation of luminosity irreversible. Take GaN/sapphire epitaxy for instance, with the dislocation average interval of merely 1 μm, photons encountered the dislocation during propagation produce scattering and generate heat. Thus, reducing defect density can increase the luminosity of LED and also lengthen its lifespan.

In order to solve the aforesaid defect problems of epitaxial film, the general approach adopts an annealing process to heat the epitaxial film to a high temperature to diffuse and rearrange the atoms inside, or induce moving of the dislocation to offset each other (such as the positive dislocation and negative dislocation move and slide in opposite directions to cancel out each other) to reduce internal stress and defect density. Reference techniques can be found in U.S. Pat. Pub. Nos. 2007/0134901, 2009/0050929, and 2010/0178749. Among them, 2007/0134901 discloses a method to grow GaAs epitaxy on a SiGe epitaxy chip. It provides first a silicon chip; next, grows a plurality of SiGe epitaxial layers with high content of Ge through an Ultra-high vacuum chemical vapor deposition (UHVCV) system; then grows a GaAs epitaxial layer on the surface of the SiGe epitaxial layer via MOCVD. In its process each layer has to go through an in-situ high temperature annealing at 750° C. for 0.25 to 1 hour, with gas of hydrogen or the like, thereby to improve the quality of the Ge film epitaxy. U.S. 2009/0050929 discloses a semiconductor substrate for epitaxy used on semiconductor photoelectric elements and method of manufacturing thereof. It grows a nitride buffer layer on a substrate surface via Atomic layer CVD (ALCVD). Then the nitride buffer layer is treated via an annealing process between temperatures 400° C. and 1,200° C. U.S. 2010/0178749 discloses a method for fabricating an epitaxy growth layer on a compound. It first grows at least one material layer via epitaxy fashion on a compound structure which includes a support substrate, a film bonded to the support substrate, and a bonding layer formed via Low pressure chemical vapor deposition (LPCVD) to be interposed between the support substrate and the film. The bonding layer is a silica formed on a bonding surface of the support substrate, or a bonding surface of the film or both. After the material layer is formed, a heat treatment for a selected duration is performed at a temperature higher than deposition of the oxide layer.

Though the aforesaid conventional manufacturing processes can reduce defect density, the temperature gradient generated during annealing tends to cause fracture of the epitaxial film. Moreover, due to the internal stress of the epitaxial film is unbalanced, when the temperature rises the lattice of the epitaxial film softens and deforms. More importantly, the general annealing process provides only limited improvement in terms of reducing the defect density of epitaxial film.

### SUMMARY OF THE INVENTION

The primary object of the present invention is to solve the problem of the conventional annealing process that cannot further reduce the defect density of epitaxial films.

To achieve the foregoing object the present invention provides an annealing method to reduce defects of epitaxial films. The method of the invention includes features as follows: apply a pressure ranged from 10 MPa to 6,000 MPa to an epitaxial film grown via vapor phase deposition on a substrate and heat the epitaxial film at a temperature lower than the melting temperature of the epitaxial film for an annealing time greater than one minute.

In one embodiment of the invention the vapor phase deposition process is metal-organic chemical vapor deposition process.

In one embodiment of the invention the pressure is applied to the epitaxial film through a pressure-transmitting medium selected from the group consisting of graphite powder, hexagonal boron nitride powder, molybdenum disulfide powder, talc powder, pyrophyllite powder, lime powder, dolomite powder and salt.

In one embodiment of the invention the pressure is applied to the epitaxial film via an isostatic pressing method or uniaxial pressing method.

In one embodiment of the invention the substrate is selected from the group consisting of sapphire, silicon carbide, gallium nitride and silicon.

In one embodiment of the invention the epitaxial film is gallium nitride or silicon.

To achieve the foregoing object the invention also provides an epitaxial film with a lower defect density formed by growing on a substrate via a vapor phase deposition process. It includes features as follows: heat the epitaxial film at a temperature lower than the melting temperature of the epitaxial film and apply a pressure ranged from 10 MPa to 6,000 MPa to the epitaxial film.

The annealing method to reduce defects of epitaxial films provided by the invention and the epitaxial film obtained therewith have many advantages over the conventional techniques, notably:

1. By applying the pressure to the epitaxial film, lattice strain of the epitaxial film is reduced, therefore defect density of the epitaxial film decreases significantly.

2. The pressure also facilitates movement of atoms in the epitaxial film so that the atoms move easier at the temperature to stable lattice positions, and the number of defects is lower.

3. By selecting the isostatic pressing method, pressure differences in all directions received by the epitaxial film can be offset as desired, thus a higher pressure can be applied to the epitaxial film without damaging the epitaxial film to get improved defect density.

The foregoing, as well as additional objects, features and advantages of the invention will be more readily apparent from the following detailed description, which proceeds with reference to the accompanying drawings.

### BRIEF DESCRIPTION OF THE DRAWINGS

FIGS. 1A through 1D are schematic views of an embodiment of the manufacturing process of the invention.

FIGS. 2A through 2D are schematic views of another embodiment of the manufacturing process of the invention.

FIG. 3 is a schematic view of a fabrication setup of yet another embodiment of the invention.

FIG. 4 is a pressure-temperature phase diagram of GaN.

### DETAILED DESCRIPTION OF THE PREFERRED EMBODIMENTS

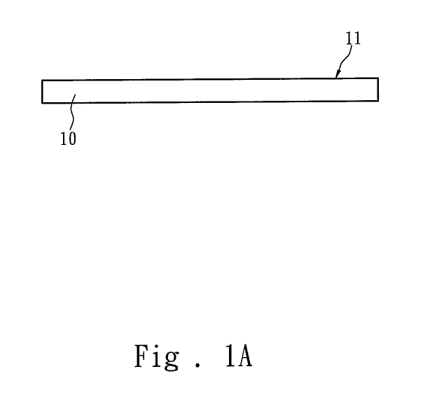

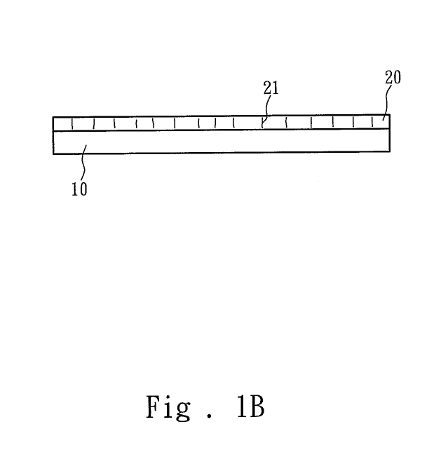

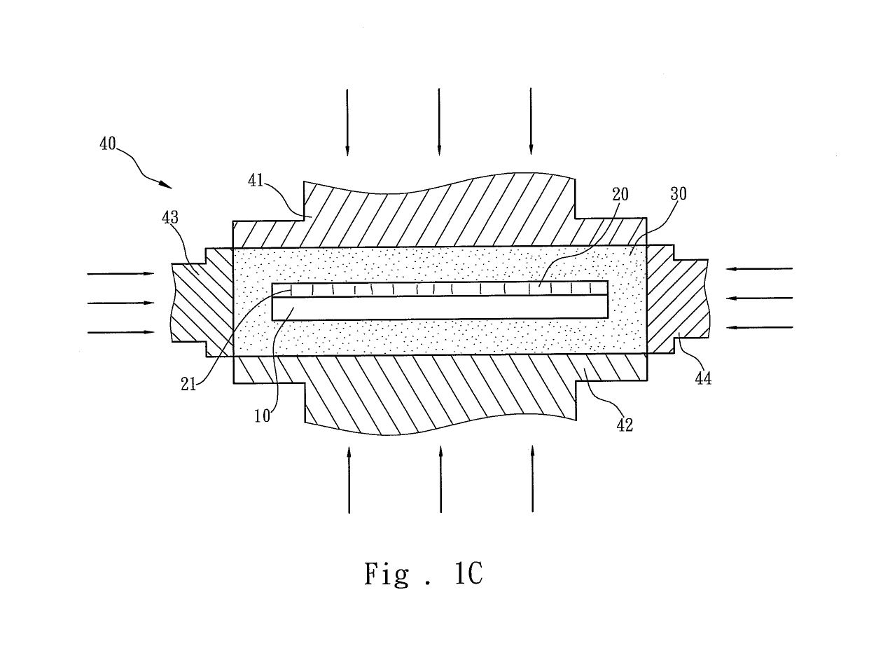

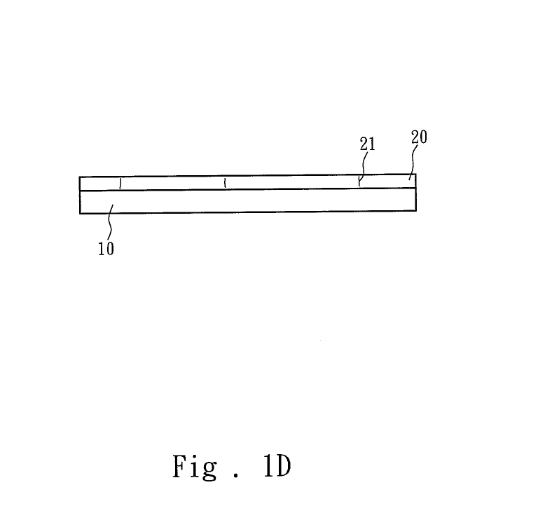

The present invention aims to provide an annealing method to reduce defects of epitaxial films and get epitaxial films therewith. Please refer to FIGS. 1A through 1D for an embodiment of the manufacturing process of the invention. As shown in FIG. 1A, first, provide a substrate 10 at a thickness between 420 μm and 440 μm in this embodiment, which is a sapphire (i.e. single crystal alumina) blade substrate cut from a sapphire crystal ingot. An upper surface 11 of the substrate 10 forms an alumina (0001) lattice plane (also called C-plane). However, the upper surface 11 is not limited to the alumina (0001) lattice plane; in practice, a (1-102-) lattice plane (or called R-plane) or (0001) lattice plane (or called M-plane) may also serve as the upper surface 11. More over, in this embodiment the sapphire crystal ingot can be fabricated and obtained via Czochralske (CZ) method, Edge-defined film-fed growth (EFG) method, Vertical horizontal gradient freezing (VHGF) method, Kyropoulos method or the like.

Referring to FIG. 1B, after the substrate 10 is prepared, grow an epitaxial film 20 on the substrate 10 at a thickness between 2 μm and 7 μm through vapor phase deposition process. In this embodiment the epitaxial film 20 is made of GaN. The vapor phase deposition process employed is preferably organic chemical vapor deposition via an organic chemical vapor deposition system, such as that made by Aixtron, Veeco or Sanso corporation. The system generally includes a reaction chamber, a vacuum pump, a heater, a gas supply unit and a gas control unit. The heater is located in the reaction chamber. The vacuum pump is connected to the reaction chamber. The gas supply unit includes a first gas source, a second gas source and a carrier gas source which are respectively connected to the reaction chamber through a piping. The gas control unit controls gas flow of the piping to adjust the gas pressure in the reaction chamber.

Take deposition of GaN for instance, first, place the substrate 10 in the reaction chamber, and vacuum the reaction chamber via the vacuum pump to a selected vacuum degree. For the GaN epitaxial film 20, the first gas source is selected from Trimethylgallium (TMG) or Triethylgallium (TEG). The second gas source is ammonia (NH₃), and the carrier gas source is hydrogen (H₂) or nitrogen (N₂). Next, heat the reaction chamber via the heater to a temperature between 500° C. and 1,000° C.; inject the mixed gas of the first gas source, second gas source and carrier gas source into the reaction chamber to grow GaN on the upper surface 11 of the substrate 10 via the chemical reaction of the gases inside the reaction chamber, and finally the epitaxial film 20 formed on the substrate 10 is obtained. While the aforesaid embodiment takes GaN as an example, it is not the limitation of the invention in terms of the parameters and reaction substances used in the organic chemical vapor deposition system. Depending on material requirements of the epitaxial film 20 to be formed, the first gas source may also be Trimethylindium (TMI), Triethylindium (TEI) or Dimethylzinc (DMZ). The second gas source may be Arsine (AsH₃) or Phosphine (PH₃).

Referring to FIG. 1B, the epitaxial film 20 has a plurality of defects 21. Take GaN as an example, before heat treatment the density of the defects 21 is about 10⁸/cm² to 10⁹/cm². In general, the defects in a single crystal include point defects, line defects, planar defects and bulk defects. The point defects include vacancy defects, interstitial defects or impurities or the like. The line defects include edge dislocation, screw dislocation or the like. The planar defects include stacking fault. The bulk defects include voids or precipitates. The defects mentioned in the invention mainly refer to line defects (i.e. edge dislocation and screw dislocation), planar defects and bulk defects.

Please referring to FIG. 1C, after the epitaxial film 20 has been formed via deposition, it is treated via an annealing process in which the epitaxial film 20 is heated to a temperature lower than the melting temperature (Tₘ) of the epitaxial film 20 and a pressure between 10 MPa and 6,000 MPa also is applied to the epitaxial film 20 at the same time. The annealing process can be performed in a high temperature atmosphere furnace, a spark plasma sintering (SPS) furnace or a heated isostaticpressure furnace. In this embodiment the high temperature atmosphere furnace made by Lindberg is employed. First, the substrate 10 and epitaxial film 20 are placed into the high temperature atmosphere furnace and encased by a pressure-transmitting medium 30 which can be graphite powder, hexagonal boron nitride powder, molybdenum disulfide powder, talc powder, pyrophyllite powder, lime powder, dolomite powder, salt or combinations thereof. These materials are in powder form in normal conditions. To facilitate process the pressure-transmitting medium 30 is preferably formed in a solid blank of a definitive shape through cold compression or hot pressing via a mold. The mold can be made of alloy steel, tungsten carbide, graphite or metals with similar characteristics thereof and ceramic. In addition, the high temperature atmosphere furnace also includes at least one pressing means 40 to provide pressure to the pressure-transmitting medium 30. To provide uniform pressure to the epitaxial film 20, the pressing means 40 is preferably set in a symmetrical manner.

As shown in FIG. 1C, in this embodiment an isostatic pressing method is employed. The pressing means 40 includes six units, while only four units are shown in the drawing. The pressing means 40 includes a first pressing unit 41, a second pressing unit 42, a third pressing unit 43 and a fourth pressing unit 44. The first and second pressing units 41 and 42 are located respectively at an upper side and a lower side of the epitaxial film 20, while the third and fourth pressing units 43 and 44 are located respectively on the left side and right side of the epitaxial film 20. In addition, a fifth pressing unit and a sixth pressing unit are provided respectively at the front side and rear side of the epitaxial film 20. While the pressing means 40 with six units is provided in this embodiment as an example, it is not the limitation of the invention. In practice the number and positioning of the pressing means 40 should take into account of providing uniform pressure to the epitaxial film 20 in every direction. Moreover, the approach of delivering the pressure from the pressing means 40 to the substrate 10 and epitaxial film 20 via the pressure-transmitting medium 30 previously discussed also serves merely for illustrative purpose and is not the limitation of the invention. In practice, the pressing means 40 can directly apply the pressure to the substrate 10 and epitaxial film 20. The pressure range of between 10 MPa and 6,000 MPa mentioned above means the pressure received by the epitaxial film 20. The actual pressure output by the pressing means 40 depends on many factors, such as whether the pressure-transmitting medium 30 is provided, the material and positioning of the pressure-transmitting medium 30 and design of the pressing means 40.

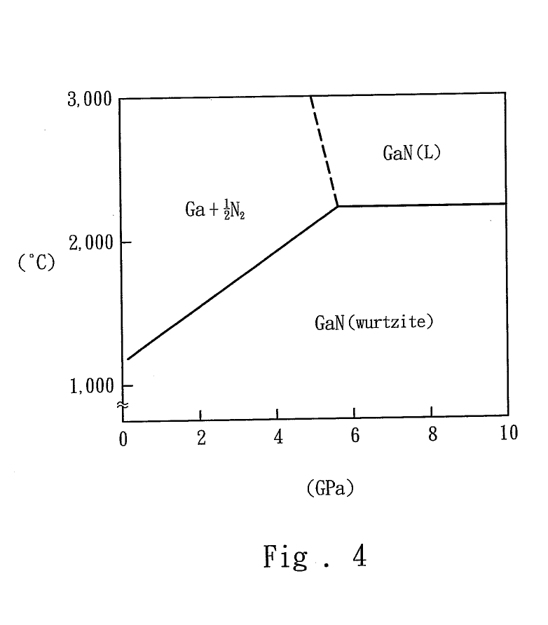

Once the substrate 10 and epitaxial film 20 are placed in the high temperature atmosphere furnace, they are heated to the temperature mentioned above and maintained at that temperature for a selected annealing time. Meanwhile, the pressing means 40 delivers the pressure via the pressure-transmitting medium 30 to the epitaxial film 20. The high temperature atmosphere furnace is maintained in an atmosphere environment by receiving injection of a selected gas, which can be nitrogen, a mixture of nitrogen and hydrogen, argon, a mixture of argon and hydrogen, or a mixture of nitrogen and argon. When the annealing time is over, the temperature and pressure in the furnace and pressing means 40 are lowered to the room temperature and normal pressure. The resulting epitaxial film 20 has fewer defects 21 inside. Referring to FIG. 1D, the selected temperature in the aforesaid process depends on material characteristics of the epitaxial film 20, preferably between 0.3Tₘ and 0.9Tₘ. With GaN used in this embodiment as an example, the melting temperature (or sublime temperature) varies depending on the pressure. FIG. 4 is a chart showing the pressure-temperature diagram of GaN. Given the pressure applied to the epitaxial film 20 between 10 MPa and 6,000 MPa, the selected temperature is ranged from 400° C. to 2,250° C. Moreover, the annealing time should be longer than one minute, and can be ranged from five minutes to ten hours, preferably between one hour and eight hours. The epitaxial film 20 obtained after the annealing process has the defect density dropped from between 10⁸/cm² and 10⁹/cm² to between 10⁴/cm² and 10⁶/cm². In addition to maintaining the temperature for the substrate 10 and epitaxial film 20 during the annealing process, the invention can also provide multi-stage heating to reach the temperature set forth above for the substrate 10 and epitaxial film 20 during the annealing process. Each stage has a shorter annealing time, for instance, first heat the substrate 10 and epitaxial film 20 to a desired temperature and maintain at that temperature for thirty minutes, then drop the temperature to the room temperature and maintain for thirty minutes, then heat to the previous temperature again, and repeat the aforesaid process as required to perform the annealing process.

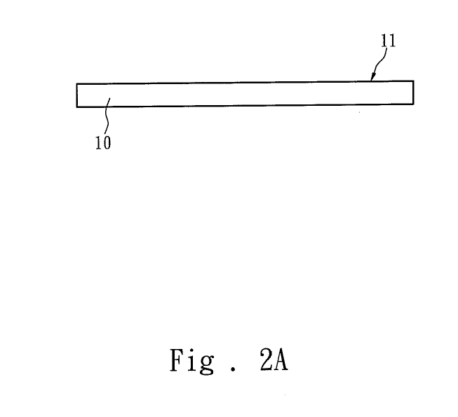

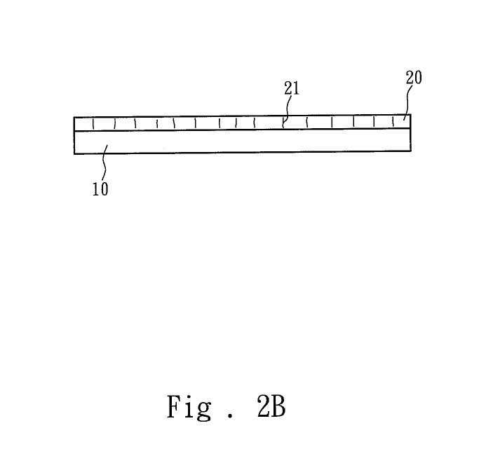

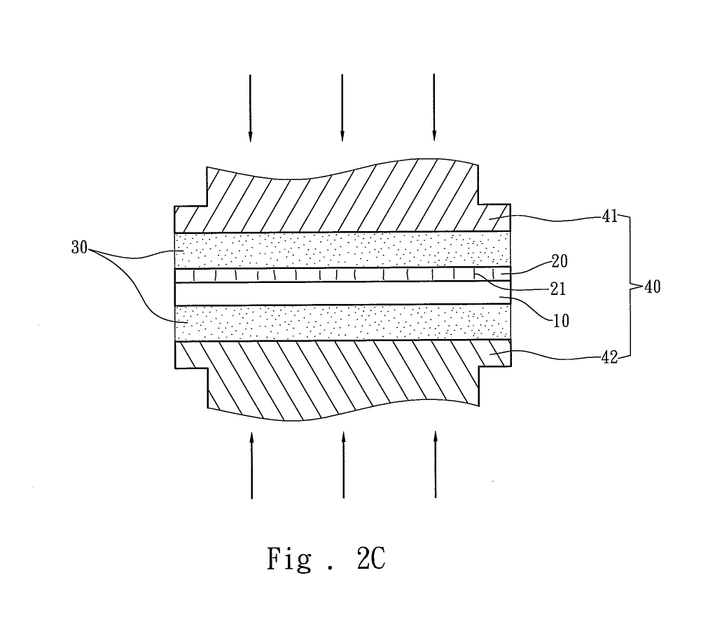

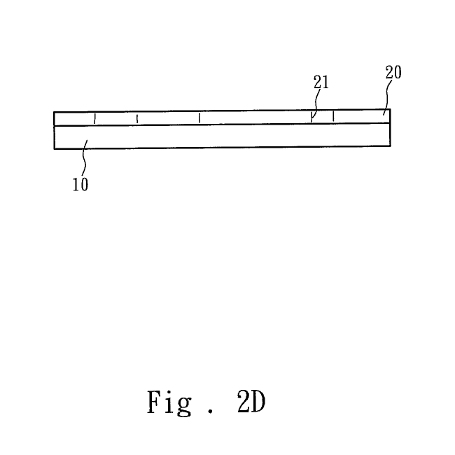

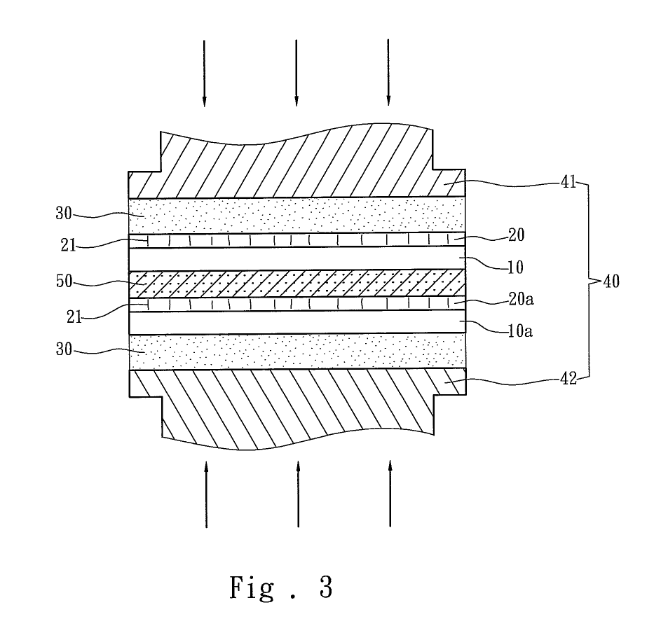

Please refer to FIGS. 2A through 2D for another embodiment of the manufacturing process of the invention. FIGS. 2A, 2B and 2D are substantially the same as FIGS. 1A, 1B and 1D of the previous embodiment, hence discussion thereof is omitted herein. This embodiment differs from the previous one by employing an uniaxial pressing method. As shown in FIG. 2C, the pressing means 40 consists of merely the first pressing unit 41 and second pressing unit 42 that are located at the upper side and lower side of the epitaxial film 20 to provide an uniaxial stress to the epitaxial film 20. Also referring to FIG. 3, yet another embodiment can be adopted in the invention for annealing multiple substrates 10 and 10a that are stacked together at the same time. First, epitaxial films 20 and 20a are grown respectively on the substrates 10 and 10a. The epitaxial film 20a also contains a plurality of defects 21; next, the substrates 10 and 10a that have the epitaxial films 20 and 20a grown respectively thereon are stacked vertically; then a pressure is applied to the stacked substrates 10 and 10a, and epitaxial films 20 and 20a via the uniaxial pressing method, and an annealing process is applied to them at the same time. In order to provide uniform stress on the epitaxial films 20 and 20a and prevent the substrate 10a or epitaxial film 20a from fracturing due to the direct pressure from the substrate 10 above, a buffer layer 50 is preferably provided between the substrate 10 and epitaxial film 20a. The buffer layer 50 can be graphite paper, nonwoven fabric made from graphite fibers, fabrics woven via knitted graphite fibers or other flexible materials formed via graphite. With the buffer layer 50 interposed therebetween, the substrate 10 and epitaxial film 20a would not direct contact each other, deformation or fracture of the substrate 10a or epitaxial film 20a under high pressure and high temperature that might otherwise occur can be averted.

In addition, according to the invention, during the epitaxial film 20 is subjected to pressure and heating at the same time, the epitaxial film 20 can be vibrated directly via a vibration source, or vibration can be rendered to the epitaxial film 20 indirectly through the pressing means and pressure-transmitting medium 30. The vibration source can be a supersonic vibrator installed in the high temperature furnace which heats the substrate 10 and epitaxial film 20. The amplitude and frequency of the vibration source are selected according to material characteristics of the epitaxial film 20. For the aforesaid epitaxial film 20 made of GaN as an example, the amplitude of the vibration source is preferably between 10 μm and 30 μm, and frequency between 20 kHz and 40 kHz. With the aid of vibration, movement of the defects 21 can be accelerated. Hence the density of the defects 21 can be reduced to a desired level in a shorter time period or at a lower temperature.

While the embodiments set forth above use LED of GaN and sapphire as an example, the method of the invention can cover any type of element fabrication involved the epitaxy technique, such as LED with other chemical compositions or structures, production of integrated circuits or fabrication of solar cells.

The invention mainly applies pressure to an epitaxial film during annealing process to reduce lattice stain of the epitaxial film, and also facilitate movement of atoms in the epitaxial film to the stable lattice positions. Compared with the conventional annealing technique that merely heats the epitaxial film without applying extra pressure, the invention can get the epitaxial film with a lower defect density, hence quality of the epitaxial film after the annealing process improves. Moreover, adopted the isostatic pressing method, when the epitaxial film receives the pressure the pressure differences in all directions can be offset as desired, thus the pressure applied to the epitaxial film can be increased and consequently reduce the stress received by the atoms in the epitaxial film, thereby accelerate elimination of the defects to get improved defect density. Furthermore, the invention can further incorporate with a vibration source to generate vibration on the epitaxial film to accelerate movement of the atoms in the epitaxial film. Thus the present invention provides significant improvements over the conventional techniques.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention set forth in the claims.

What is claimed is:

1. An annealing method to reduce defects of epitaxial films, comprising:
applying a pressure ranged from 10 MPa to 6,000 MPa to an epitaxial film grown on a substrate through a vapor phase deposition process; and
heating the epitaxial film to a temperature lower than the melting temperature thereof.

2. The annealing method of claim 1, wherein the vapor phase deposition process is a metal-organic chemical vapor deposition process.

3. The annealing method of claim 1, wherein the pressure is applied to the epitaxial film through an isostatic pressing or uniaxial pressing method.

4. The annealing method of claim 1, wherein the substrate is selected from the group consisting of sapphire, silicon carbide, gallium nitride and silicon.

5. The annealing method of claim 1, wherein the epitaxial film is gallium nitride or silicon.

6. The annealing method of claim 1, wherein the substrate is formed at a thickness ranged from 420 μm to 440 μm.

7. The annealing method of claim 1, wherein the epitaxial film is formed at a thickness ranged from 2 μm to 7 μm.

8. The annealing method of claim 1, wherein the pressure is applied to the epitaxial film through a pressure-transmitting medium which is selected from the group consisting of graphite powder, hexagonal boron nitride powder, molybdenum disulfide powder, talc powder, pyrophyllite powder, lime powder, dolomite powder and salt.

9. The annealing method of claim 1, wherein the epitaxial film is placed in an atmospheric environment which contains gas selected from the group consisting of nitrogen, a mixture of nitrogen and hydrogen, argon, a mixture of argon and hydrogen, and a mixture of nitrogen and argon.

10. The annealing method of claim 1, wherein the epitaxial film is held in a vibration environment.

11. The annealing method of claim 1, wherein the epitaxial film is kept at the temperature for an annealing time greater than one minute.

12. The annealing method of claim 11, wherein the annealing time is ranged from five minutes to ten hours.

13. An epitaxial film having a low defect density and grown on a substrate through a vapor phase deposition process, the epitaxial film being treated through annealing which comprises the steps of:
heating the epitaxial film to a temperature lower than the melting temperature thereof; and
applying a pressure ranged from 10 MPa to 6,000 MPa to the epitaxial film.

14. The epitaxial film of claim 13, wherein the vapor phase deposition process is a metal-organic chemical vapor deposition process.

15. The epitaxial film of claim 13, wherein the pressure is applied to the epitaxial film through the isostatic pressing or uniaxial pressing method.

16. The epitaxial film of claim 13, wherein the substrate is selected from the group consisting of sapphire, silicon carbide, gallium nitride and silicon.

17. The epitaxial film of claim 13, wherein the epitaxial film is gallium nitride or silicon.

18. The epitaxial film of claim 13, wherein the substrate is formed at a thickness ranged from 420 μm to 440 μm.

19. The epitaxial film of claim 13, wherein the epitaxial film is formed at a thickness ranged from 2 μm to 7 μm.

20. The epitaxial film of claim 13, wherein the pressure is applied to the epitaxial film through a pressure-transmitting medium which is selected from the group consisting of graphite powder, hexagonal boron nitride powder, molybdenum disulfide powder, talc powder, pyrophyllite powder, lime powder, dolomite powder and salt.
